(19) United States
(12) Patent Application Publication
(10) Pub. No.: US 2024/0417856 A1
(43) Pub. Date: Dec. 19, 2024

(54) SUSCEPTOR

(71) Applicant: POINT ENGINEERING CO., LTD., Asan-si (KR)

(72) Inventors: Bum Mo AHN, Suwon-si (KR); Young Heum EOM, Anyang-si (KR); Jun Young CHOI, Asan-si (KR)

(21) Appl. No.: 18/704,378

(22) PCT Filed: Oct. 19, 2022
(86) PCT No.: PCT/KR2022/015938

§ 371 Date: Apr. 24, 2024

(30) Foreign Application Priority Data
Oct. 28, 2021 (KR) 10-2021-0145177
Oct. 28, 2021 (KR) 10-2021-0145178

(51) Int. Cl. C23C 16/458

(52) U.S. Cl. CPC C23C 16/4586

(57) ABSTRACT

The present invention relates to a susceptor which seats a substrate on the upper surface thereof during a deposition process for the substrate, the susceptor comprising: a first plate; a second plate provided under the first plate; and a planar heater provided between the first and second plates, wherein the planar heater is in the form of a plane, and a heating pattern formed to have a large area corresponding to the area of the plane is provided inside the planar heater. Accordingly, the present invention provides a susceptor in which a uniform temperature is formed over the entire area thereof without the risk of disconnection.

### TECHNICAL FIELD

The present disclosure relates to a susceptor for seating a substrate on an upper surface thereof.

### BACKGROUND ART

Technologies for depositing thin films on semiconductor substrates or display glass include chemical vapor deposition (CVD), which forms thin films through chemical reactions.

A deposition process for a substrate generally takes place inside a vacuum chamber. Here, a susceptor is installed inside the vacuum chamber. The susceptor has a heater therein. With this, the substrate placed on an upper surface of the susceptor can be heated to a temperature appropriate for deposition.

The susceptor may be provided with a pipe-shaped sheath heater as a heater. The sheath heater is received in an insertion recess formed in the body of the susceptor. The sheath heater is inserted into the insertion recess and then sealed in the inserted form by a sealing cover corresponding to the insertion recess. While the sheath heater is installed in the insertion recess sealed by the sealing cover, the insertion recess may be welded using at least one of common welding methods such as argon welding, electron beam, or brazing. The installation of the sheath heater inside the susceptor is completed by sealing the insertion recess with the sealing cover and then welding it.

However, the sheath heater is provided only in the insertion recess formed in a limited partial area of the entire area of the susceptor. As a result, a temperature difference occurs on the susceptor between a position with the sheath heater and a position without the sheath heater and far from the sheath heater. In other words, the temperature of the entire area corresponding to the entire area of the susceptor becomes non-uniform. The non-uniform temperature can be solved to some extent over time, but it takes a long period of time to solve such temperature non-uniformity.

Since the pipe-shaped sheath heater is installed in the insertion recess of the susceptor, it has a relatively smaller area than the entire area of the susceptor. Therefore, the sheath heater has limitations in raising the temperature of the susceptor uniformly.

To overcome this, it may be considered to increase the heat generation amount per unit area of the sheath heater. However, in this case, the sheath heater may cause disconnection due to its heating wire-type pipe shape.

In addition, in the case of the insertion recess corresponding to the shape of the sheath heater, it may be cumbersome in that the insertion recess has to be formed in response to the bending direction of the sheath heater at the position where the sheath heater is intended to be installed.

Moreover, there is a problem in that the design of the insertion recess has to be updated every time according to the standards or specifications of the sheath heater.

### DISCLOSURE

### Technical Problem

Accordingly, the present disclosure has been made keeping in mind the above problems occurring in the related art, and an objective of the present disclosure is to provide a susceptor that enables a uniform temperature to be formed over the entire area thereof without the risk of disconnection.

Another objective of the present disclosure is to provide an internal space for installing a heater regardless of a bending direction of the heater and to prevent surface flatness of the susceptor from deteriorating.

### Technical Solution

In order to accomplish the above objectives, according to one aspect of the present disclosure, there is provided a susceptor, including: a first plate; a second plate provided under the first plate; and a planar heater provided between the first and second plates. The planar heater may be in the form of a planar surface and may include a heating pattern therein corresponding to an area of the planar surface.

In addition, the planar heater may include: a first film; a second film provided under the first film; and a heating pattern formed on at least one of the first and second films and provided between the first and second films.

In addition, the heating pattern may be formed corresponding to an area of a planar surface of at least one of the first and second films.

In addition, the planar heater may include: at least one post hole; and a terminal portion provided at a side of the planar heater.

In addition, the planar heater may be divided. The divided planar heater may be disposed so that the terminal portion of the planar heater corresponds to a hollow shaft of the second plate.

In addition, at least one of the first and second plates may include a post and a remaining one of the first and second plates may include a post insertion portion. The first and second plates may be joined by welding an insertion area where the post is inserted into the post insertion portion.

In addition, the planar heater may include at least one post hole corresponding to the post and the post insertion portion, and the susceptor may include a lift pin hole provided in a welding area corresponding to the post hole, the post, and the post insertion portion.

In addition, the at least one post hole may include a plurality of post holes. A portion of the post holes may have a relatively large size and a remaining portion of the post holes may have a relatively small size, and the lift pin hole may be provided in the post hole having the large size.

In addition, the second plate may include a hollow shaft extending 1 center thereof toward a floor surface. The planar heater may be disposed so that the terminal portion corresponds to the hollow shaft.

In addition, the susceptor may include a heater seating recess provided in at least one of the first and second plates.

According to another aspect of the present disclosure, there is provided a susceptor provided by joining a first plate and a second plate together. At least one of the first and second plates may include a post and a remaining one of the first and second plates comprises a post insertion portion. An internal space in which a heater is provided may be provided inside a border portion of the at least one of the first and second plates, and the post may be provided in the internal space. Border portions of the first and second plates may be welded and integrated together, and an insertion area where the insertion portion where the post is inserted into the post insertion portion may be welded.

In addition, the insertion area may be welded by friction stir welding.

In addition, the heater may be provided as a planar heater. The planar heater may include: a first film; a second film provided under the first film; and a heating pattern formed on at least one of the first and second films and provided between the first and second films. The heating pattern may be formed corresponding to an area of a planar surface of at least one of the first and second films.

In addition, the planar heater may include: at least one post hole; and a terminal portion provided at a side of the planar heater.

In addition, the post hole may correspond to the post provided in the at least one of the first and second plates and the post insertion portion provided in the remaining one of the first and second plates, and the susceptor may include a lift pin hole provided in a welding area corresponding to the post hole, the post, and the post insertion portion.

In addition, the second plate may include a hollow shaft extending from a center thereof toward a floor surface. The planar heater may be disposed so that the terminal portion corresponds to the hollow shaft.

### Advantageous Effects

A susceptor according to the present disclosure is provided with a planar heater in surface contact with first and second plates of the susceptor and includes a heating pattern corresponding to the area of a contact surface thereof. Therefore, the entire area of the susceptor according to the present disclosure can be heated uniformly.

In addition, the susceptor according to the present disclosure includes a heating pattern formed with a large area corresponding to the area of a planar surface of the planar heater. Therefore, the heat generation amount per unit area of the heating pattern is lower than that of a heater (for example, a sheath heater) provided with heating wires in only some areas even when the temperature is raised to a high temperature. This can minimize the risk of disconnection.

In addition, the susceptor according to the present disclosure has an internal space with a large bottom surface. Therefore, a heater can be easily installed in the internal space regardless of the shape of the heater. This can increase the efficiency of installing the heater.

In addition, the susceptor according to the present disclosure has a mechanical coupling area between a post and a post insertion portion at both central and peripheral portions of the susceptor, and the post and the post insertion portion are integrated by welding. Therefore, when the susceptor is heated by the heater provided in the internal space of the susceptor, deterioration of surface flatness of the susceptor caused by a difference in flatness between the peripheral portion of the susceptor and the central portion of the susceptor can be prevented.

### DESCRIPTION OF DRAWINGS

FIG. 1 is a view schematically illustrating semiconductor manufacturing process equipment or display manufacturing process equipment including a susceptor according to a preferred embodiment of the present disclosure.

FIG. 2 is an exploded perspective view illustrating a susceptor according to a preferred embodiment of the present disclosure.

FIG. 3 is a partial sectional perspective view illustrating the susceptor according to the preferred embodiment of the present disclosure.

FIG. 4 is a view illustrating a planar heater according to the preferred embodiment of the present disclosure when viewed from above.

FIG. 5 is a view illustrating a divided unit of the planar heater according to the preferred embodiment of the present disclosure.

FIG. 6 is an exploded side sectional view illustrating the susceptor according to the preferred embodiment of the present disclosure.

FIG. 7 is a view schematically illustrating the susceptor according to the preferred embodiment of the present disclosure cut along line A-A′ of FIG. 4.

FIG. 8 is a view illustrating the process of fastening and integrating first and second plates.

FIG. 9 is a view illustrating a welded state of the first and second plates when viewed from above.

FIG. 10 is a view illustrating the susceptor according to the preferred embodiment of the present disclosure cut along line B-B′ of FIG. 4.

### MODE FOR INVENTION

Contents of the description below merely exemplify the principle of the present disclosure. Therefore, those of ordinary skill in the art may implement the theory of the present disclosure and invent various apparatuses which are included within the concept and the scope of the present disclosure even though it is not clearly explained or illustrated in the description. Furthermore, in principle, all the conditional terms and embodiments listed in this description are clearly intended for the purpose of understanding the concept of the present disclosure, and one should understand that the present disclosure is not limited to the exemplary embodiments and the conditions.

The above described objectives, features, and advantages will be more apparent through the following detailed description related to the accompanying drawings, and thus those of ordinary skill in the art may easily implement the technical spirit of the present disclosure.

The embodiments of the present disclosure are described with reference to sectional views and/or perspective views which schematically illustrate ideal embodiments of the present disclosure. For explicit and convenient description of the technical content, thicknesses of films and regions in the figures may be exaggerated. As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. The technical terms used herein are for the purpose of describing particular embodiments only and should not be construed as limiting the present disclosure. As used herein, the singular forms are intended to include the plural forms as well, unless the context clearly indicates otherwise. It will be further understood that the terms “comprise” and/or “include” when used in this specification, specify the presence of stated features, integers, steps, operations, elements, components, and/or combinations thereof but do not preclude the presence or addition of one other features, integers, steps, operations, or more elements, components, and/or combinations thereof.

Hereinbelow, preferred embodiments of the present disclosure will be described in detail with reference to the accompanying drawings.

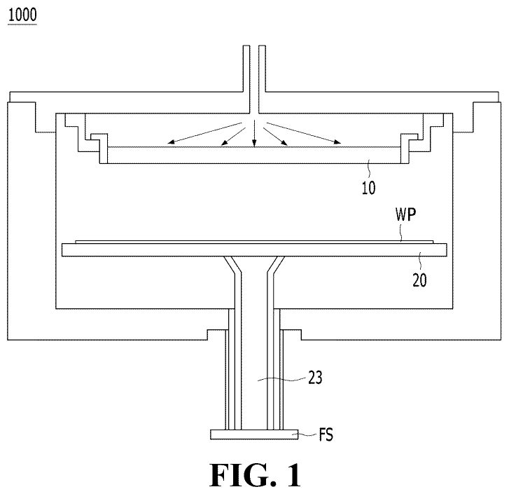

FIG. 1 is a view schematically illustrating semiconductor manufacturing process equipment or display manufacturing process equipment 1000 according to a preferred embodiment of the present disclosure.

The semiconductor manufacturing process equipment or display manufacturing process equipment 1000 includes etching equipment, cleaning equipment, heat treatment equipment, ion implantation equipment, sputtering equipment, or CVD equipment. Hereinafter, the semiconductor manufacturing process equipment or display manufacturing process equipment 1000 may be CVD equipment as an example.

CVD equipment deposits a thin film on the surface of a wafer or glass through deposited electrons or chemical reactions occurring in the gas phase by exciting a reaction process fluid composed of elements with energy such as thermal plasma or discharge photo energy. The CVD equipment includes normal pressure CVD equipment, reduced pressure CVD equipment, plasma CVD equipment, photo CVD equipment, and MO-CVD equipment.

As illustrated in FIG. 1, the semiconductor manufacturing process equipment or display manufacturing process equipment 1000 according to the preferred embodiment of the present disclosure includes a supply means 10 for supplying a reaction process fluid or gas; and a susceptor according to a preferred embodiment of the present disclosure for seating a substrate (WP) configured as a wafer or glass thereon according to a semiconductor manufacturing process or a display manufacturing process.

The supply means 10 is configured as a showerhead that supplies a reaction process fluid onto the substrate WP when it is provided in CVD equipment as the semiconductor manufacturing process equipment 1000. Meanwhile, the supply means 10 is configured as a diffuser that sprays gas when it is provided in CVD equipment as the display manufacturing process equipment 1000.

When a thin film process for the substrate WP seated on an upper surface of the susceptor 20 is completed, the susceptor 20 lifts the substrate WP through a lift pin provided in the susceptor. Accordingly, the substrate WP on which a film is formed may be moved to another position.

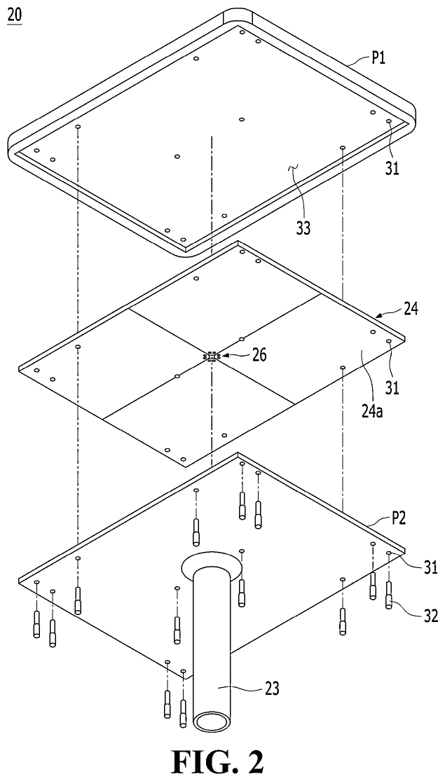

FIG. 2 is an exploded perspective view illustrating the susceptor 20 according to the preferred embodiment of the present disclosure.

The susceptor 20 according to the preferred embodiment of the present disclosure includes a first plate P1, a second plate P2 provided under the first plate P1, and a planar heater 24 provided between the first and second plates P1 and P2.

The first plate P1 is provided in a shape with a planar surface. The first plate P1 is made of aluminum or a ceramic material. When the first plate P1 is made of aluminum or an aluminum alloy material, surfaces thereof may be anodized. The first plate P1 provides a surface coming into direct contact with the substrate WP through an upper surface thereof.

The second plate P2 is provided under the first plate P1. The second plate P2 is made of aluminum or a ceramic material. When the second plate P2 is made of aluminum or an aluminum alloy material, surfaces thereof may be anodized. The second plate P2 includes a body BD, a post 22 protruding from the body BD in a direction toward the first plate P1, and a hollow shaft 23 extending from a center thereof toward a floor surface. The hollow shaft 23 has an empty space therein to accommodate various power cables connected to the planar heater 24.

Referring to FIG. 1, the hollow shaft 23 is connected to a floor support FS. The floor support FS is connected to the hollow shaft 23 to support the second plate P2, the first plate P1 provided on the second plate P2, and the planar heater 24 provided between the first and second plates P1 and P2 from the floor surface.

The susceptor 20 according to the preferred embodiment of the present disclosure may include a heater seating recess 33 in at least one of the first and second plates P1 and P2. Referring to FIG. 2, the susceptor 20 according to the preferred embodiment of the present disclosure is provided with a concave heater seating recess 33 in a lower surface of the first plate P1.

The heater seating recess 33 functions to receive the planar heater 24. Accordingly, the heater seating recess 33 may be formed to have an area equal to or a predetermined amount larger than the entire area of the planar heater 24.

The planar heater 24 is provided in the heater seating recess 33 and is positioned inside the first plate P1.

In the susceptor 20 according to the preferred embodiment of the present disclosure, the first and second plates P1 and P2 are coupled to each other with the planar heater 24 provided in the heater seating recess 33. Before the first and second plates P1 and P2 are coupled, one surface of the planar heater 24 is exposed toward the second plate P2. In the susceptor 20 according to the preferred embodiment of the present disclosure, the first and second plates P1 and P2 are coupled to each other to seal the heater seating recess 33 through the second plate P2. With this, the planar heater 24 may be provided between the first and second plates P1 and P2 so as not to be exposed to the outside. The first and second plates P1 and P2 are joined together by welding. The joining of the first and second plates P1 and P2 is preferably achieved by friction stir welding.

The planar heater 24 is in the form of a planar surface and includes a heating pattern HP therein corresponding to the area of the planar surface.

Accordingly, the planar heater may uniformly heat the first and second plates P1 and P2 between the first and second plates P1 and P2.

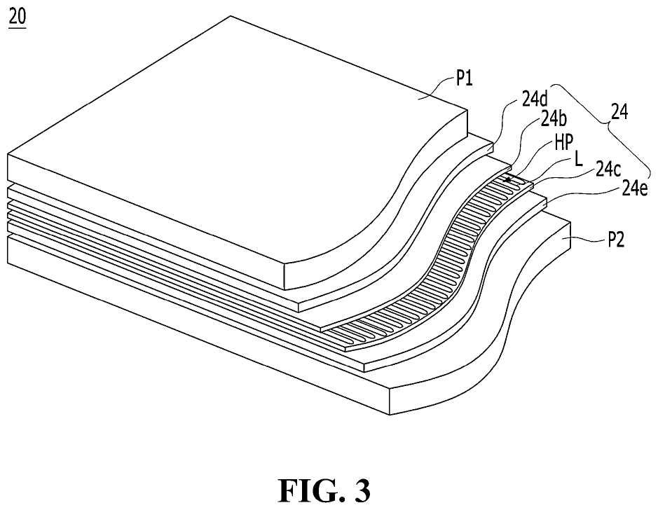

FIG. 3 is a partial sectional perspective view illustrating the susceptor 20 according to the preferred embodiment of the present disclosure. In FIG. 3, the planar heater 24 between the first and second plates P1 and P2 is in a disassembled state.

As illustrated in FIG. 3, the planar heater 24 according to the preferred embodiment of the present disclosure includes a first film 24b, a second film 24c provided under the first film 24b, and a heating pattern HP provided between the first and second films 24b and 24c.

The planar heater 24 according to the preferred embodiment of the present disclosure may additionally include a cover inside the heater seating recess 33 to increase durability. Referring to FIG. 3, a first cover 24d is provided on the first film 24b, and a second cover 24e is provided under the second film 24c. The planar heater 24 according to the preferred embodiment of the present disclosure may have surfaces defined by the first and second covers 24d and 24e.

The first and second covers 24d and 24e are preferably provided to have a thin thickness of 1.0 mm. The first and second covers 24d and 24e may correspond to the first and second films 24b and 24c, respectively, and may be attached to the first and second films 24b and 24, respectively.

The first film 24b is preferably provided to have a very thin thickness of 0.5 mm. The first film 24b is made of an insulating material. Specifically, the first film 24b is made of mica, an insulating material, and has the advantages of heat resistance and excellent thermal shock absorption.

The second film 24c is made of the same material as that of the first film 24b and has the same thickness as that of the first film. Specifically, the second film 24c is made of mica, an insulating material, and has a very thin thickness of 0.5 mm.

In the planar heater 24 according to the preferred embodiment of the present disclosure, the first and second films 24b and 24c are provided to have a thickness of 0.5 mm, and the second covers 24d and 24e respectively attached to the first and second films 24b and 24c are provided to have a thickness of 1.0 mm. Accordingly, the planar heater 24 according to the preferred embodiment of the present disclosure is formed to have a thin thickness of 3 mm.

The heating pattern HP is formed on at least one of the first and second films 24b and 24c, and is formed corresponding to the area of a planar surface of at least one of the first and second films. In the planar heater 24 according to the preferred embodiment of the present disclosure, the heating pattern HP is formed on an upper surface of the second film 24c. Accordingly, the heating pattern HP is formed corresponding to the area of the planar surface of the second film 24c.

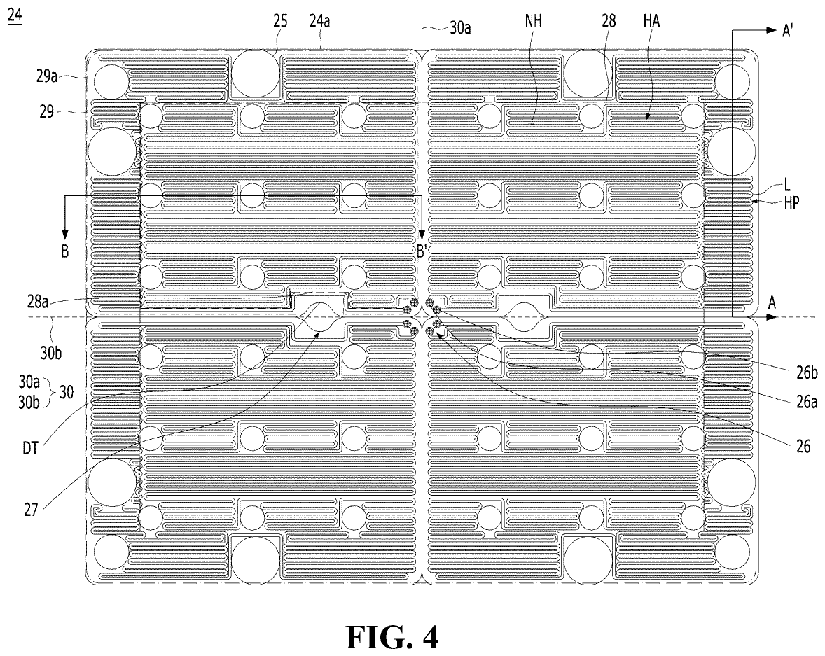

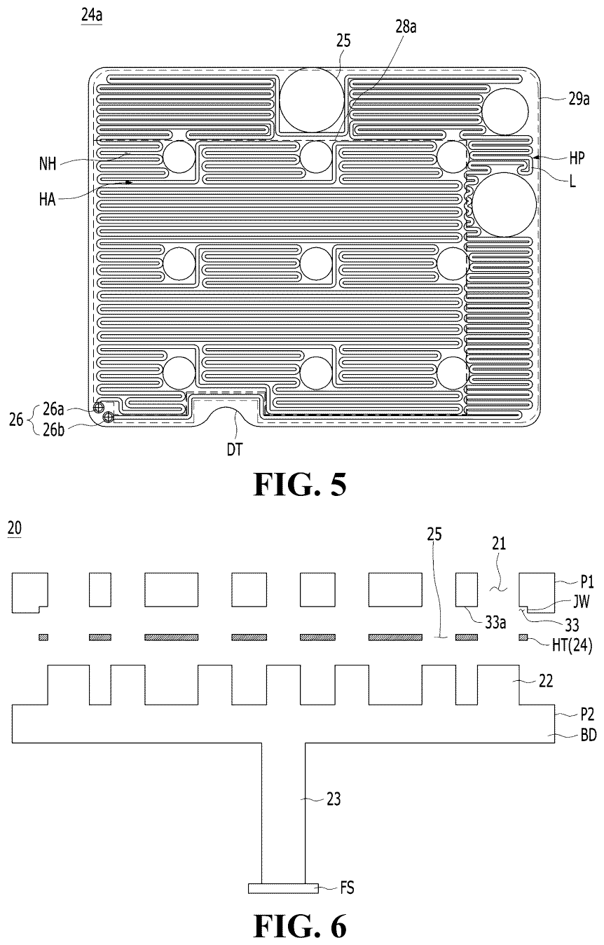

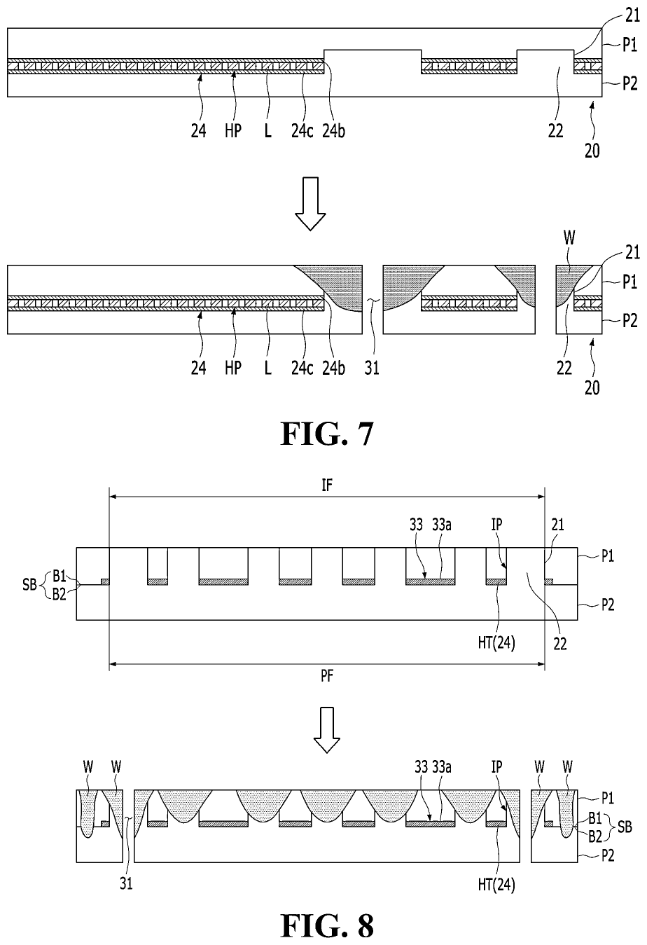

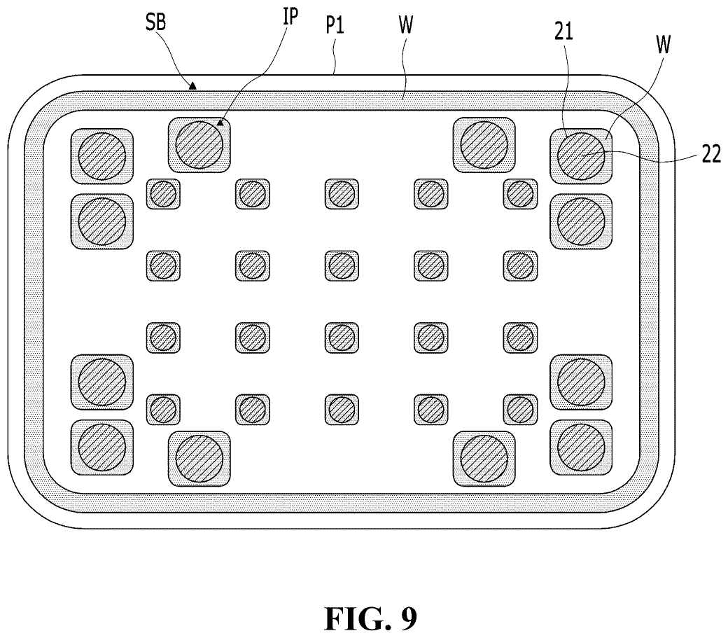

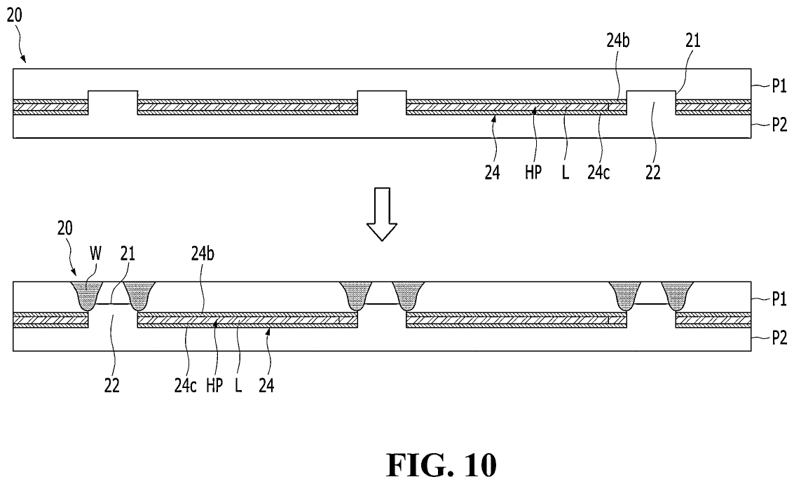

FIG. 4 is a view illustrating the planar heater 24 according to the preferred embodiment of the present disclosure when viewed from above. FIG. 5 is a view illustrating a divided unit of the planar heater 24 according to the preferred embodiment of the present disclosure. FIG. 6 is an exploded side sectional view illustrating the susceptor 20 according to the preferred embodiment of the present disclosure. FIG. 7 is a view schematically illustrating the susceptor 20 according to the preferred embodiment of the present disclosure cut along line A-A′ of FIG. 4. FIG. 8 is a view illustrating the process of fastening and integrating first and second plates P1 and P2. FIGS. 9 and 5 are views illustrating a welded state of the first and second plates P1 and P2 when viewed from above. FIG. 10 is a view illustrating the susceptor 20 according to the preferred embodiment of the present disclosure cut along line B-B′ of FIG. 4.

As illustrated in FIGS. 4 and 5, in the planar heater 24 according to the preferred embodiment of the present disclosure, the heating pattern HP is formed on the second film 24c and the first film 24b is provided on the heating pattern HP so that the heating pattern HP is provided in the planar heater.

The heating pattern HP is formed by a heating line L. The heating line L is made of SUS series. Therefore, the heating pattern HP is made of SUS series.

The heating line L has a first end connected to at least one of a positive terminal and a negative terminal and a second end connected to the remaining one. As an example, the first end of the heating line L is connected to the positive terminal and the second end thereof is connected to the negative terminal.

The first end of the heating line L is connected to a first terminal 26a of a terminal portion 26 serving as the positive terminal, and the second end thereof is connected to a second terminal 26b of the terminal portion 26 serving as the negative terminal. Here, the terminal portion 26 is exposed to the outside through a first terminal opening provided in the first film 24b. The first terminal opening is provided at a position corresponding to the terminal portion 26. When the first cover 24d is provided on the first film 24b, the first cover 24d may have a second terminal opening at a position corresponding to the first terminal opening. With this, the terminal portion 26 is exposed to the outside of the planar heater 24.

The heating line L is one continuous line and forms a predetermined pattern on the second film 24c. The planar heater 24 according to the preferred embodiment of the present disclosure includes at least one post hole 25 and the terminal portion 26 provided at a side thereof. Here, the heating line L is disposed in an area excluding the area where the post hole 25 and the terminal portion 26 are formed among the entire area of the upper surface of the second film 24c to form the heating pattern HP.

In other words, the heating pattern HP is formed on an upper surface of a non-hole forming area NH where the post hole 25 and the terminal 26 are not formed among the entire area of the upper surface of the second film 24c.

The non-hole forming area NH is an area where the post hole 25 or the terminal portion 26 is not formed and has a planar shape. As the heating pattern HP is formed in the non-hole forming area NH, it is formed corresponding to the area of the planar surface of the second film 24c.

The heating pattern HP is formed in a form in which the non-hole forming area NH is covered with the heating line L. Specifically, the heating line L covers the non-hole forming area NH by bending it from the first end thereof connected to the positive terminal at a small separation distance so that abutting portions of the heating line L do not overlap each other. The heating pattern HP may have a density that is relatively increased or relatively decreased by adjusting the separation distance between the abutting portions of the heating line L. With this, the temperature of the planar surface area of the planar heater 24 according to the preferred embodiment of the present disclosure may be made more even.

Referring to FIG. 4, the planar heater 24 according to the preferred embodiment of the present disclosure is divided. As an example, the planar heater 24 according to the preferred embodiment of the present disclosure may be divided into four and include four unit planar heaters 24a.

Each of the unit planar heaters 24a is disposed with the terminal portion 26 corresponding to the hollow shaft 23 of the second plate P2. Accordingly, the unit planar heaters 24a are arranged so that the respective terminal portions 26 of the unit planar heaters 24a are positioned close together and face each other. The terminal portion 26 of each of the unit planar heaters 24a is positioned corresponding to an inner hollow of the hollow shaft 23 and is thus positioned in the center of the second plate P2. Accordingly, the planar heater 24 according to the preferred embodiment of the present disclosure is disposed so that the terminal portion 26 is positioned corresponding to the hollow shaft 23 of the second plate P2.

The planar heater 24 according to the preferred embodiment of the present disclosure includes a central area 28 positioned close to the terminal portion 26 with respect to the central terminal portion 26 and a peripheral area 29 surrounding the central area 28. Here, the central area 28 and the peripheral area 29 are provided discontinuously with a division boundary 30 due to the divided shape of the planar heater 24 according to the preferred embodiment of the present disclosure.

Each of the unit planar heaters 24a includes a unit central area 28a constituting the central area 28 and a unit peripheral area 29a constituting the peripheral area.

The central area 28 is provided with the terminal portion 26.

The heating line L is provided in a form that covers the unit central area 28a from the terminal portion 26 and then covers the unit peripheral area 29a.

Specifically, the heating line L covers the unit central area 28a by bending it from the first end thereof corresponding to the first terminal 26a so that the abutting portions of the heating line L do not overlap each other. The heating line L is bent and disposed in a form that maximally covers the non-hole forming area NH positioned around the first terminal 26a.

The heating line L covers the entire unit central area 28a, and covers the unit peripheral area 29a while surrounding the unit central area 28a from the second end thereof.

The planar heater 24 according to the preferred embodiment of the present disclosure may have a density that is relatively decreased by relatively increasing the separation distance between the abutting portions of the heating line L in the unit central area 28a. In this case, the density may be relatively increased by relatively decreasing the separation distance between the abutting portions of the heating line L in the unit peripheral area 29a.

In the planar heater 24 according to the preferred embodiment of the present disclosure, when the density of the heating line L in at least one of the unit central area 28a and the unit peripheral area 29a is increased, the density of the heating line in the remaining one may be decreased. With this, the planar heater 24 according to the preferred embodiment of the present disclosure may more effectively equalize the temperatures of the central area 28 and the peripheral area 29, which include the unit central area 28a and the unit peripheral area 29a.

The planar heater 24 according to the preferred embodiment of the present disclosure has a structure in which it is in surface contact with each of the first and second plates P1 and P2 between the first and second plates P1 and P2. This structure may be achieved by attaching the first and second films 24b and 24c to the top and bottom of the heating pattern HP, respectively, to form a planar-shaped heating surface, and forming the heating pattern HP corresponding to the area of the heating surface to provide a planar-shaped heating element. Here, temperature non-uniformity may be improved by increasing the density of at least a portion of the entire area (specifically, the peripheral area 29) of the heating pattern HP and decreasing the density of the remaining portion (specifically, the central area 28).

Unlike the planar heater 24 according to the preferred embodiment of the present disclosure, a sheath heater has a pipe shape and therefore does not have a structure in which it is in planar surface contact with the first and second plates P1 and P2. Therefore, it takes a long period of time to make the temperature uniform over the entire area of the susceptor.

However, the planar heater 24 according to the preferred embodiment of the present disclosure is formed as a planar heating element by forming the heating pattern HP corresponding to the area of the first and second films 24b and 24c that function as heating surfaces. With this, when provided between the first and second plates P1 and P2, the planar heater is enabled to be in surface contact with the first and second plates P1 and P2 in a parallel form.

In the planar heater 24 according to the preferred embodiment of the present disclosure, the planar heater 24 is in surface contact with the first and second plates P1 and P2 and includes the heating pattern HP corresponding to the area of a contact surface thereof. Accordingly, the planar heater 24 according to the preferred embodiment of the present disclosure may uniformly heat the entire area of the susceptor 20 according to the preferred embodiment of the present disclosure.

The planar heater 24 according to the preferred embodiment of the present disclosure includes the heating pattern HP corresponding to the area of the planar surface of the planar heater 24. Therefore, the area of a heating pattern existing area HA provided by forming the heating pattern HP is large. The planar heater 24 according to the preferred embodiment of the present disclosure includes the heating pattern HP in a form that covers a large area, so even when the heat generation amount per unit area is low, the overall temperature of the susceptor 20 according to the preferred embodiment of the present disclosure may be raised uniformly.

In addition, the planar heater 24 according to a preferred embodiment of the present disclosure has a low heat generation amount per unit area of the heating pattern HP compared to a heater (for example, a sheath heater) provided with heating wires only in some areas even when the temperature is raised to a high temperature. Therefore, the risk of disconnection may be minimized.

Specifically, the planar heater 24 according to the preferred embodiment of the present disclosure is in a form in which the remaining area (area corresponding to the non-hole forming area NH) excluding the post hole 25 in the area of the planar surface of the planar heater 24 is entirely covered with the heating pattern HP. Therefore, the planar heater 24 according to the preferred embodiment of the present disclosure includes the heating pattern HP that occupies a large area by covering the planar surface area. Accordingly, the planar heater 24 according to the preferred embodiment of the present disclosure has a low heat generation amount per unit area compared to the sheath heater, which heats only a portion of the planar surface area due to its pipe shape, even when the temperature is raised to equal to or higher than 400° C. As a result, the planar heater 24 according to the preferred embodiment of the present disclosure may improve temperature uniformity without posing the risk of disconnection. The planar heater 24 according to the preferred embodiment of the present disclosure may increase the temperature to equal to or higher than 400° C., preferably to 470° C., without causing the problem of product damage due to disconnection. With this, the planar heater 24 according to the preferred embodiment of the present disclosure may effectively enable the first plate P1, which is in direct contact with the substrate WP and transfers heat, to reach a target temperature.

Referring to FIGS. 4 and 5, the planar heater 24 according to the preferred embodiment of the present disclosure is provided with a plurality of post holes 25. Here, at least a portion of the post holes 25 has a relatively large size and the remaining portion has a relatively small size.

Specifically, the post holes 25 provided in the peripheral area 29 are provided in a relatively large size. Meanwhile, the post holes 25 provided in the central area 28 are provided in a relatively small size.

The post holes 25 provided in the unit peripheral area 29a constituting the peripheral area 29 are provided in a relatively large size, and the post holes 25 provided in the unit central area 28a having the central area 28 are provided in a relatively small size.

The susceptor 20 according to the preferred embodiment of the present disclosure may have an internal space 33 for providing a heater HT inside a border portion of at least one of the first and second plates P1 and P2. Referring to FIGS. 2 and 6, the susceptor 20 according to the preferred embodiment of the present disclosure may have the internal space 33 in the first plate P1.

The internal space 33 is formed concavely in a lower portion of the first plate P1. Referring to FIG. 2, a bottom surface 33a of the internal space 33 has a planar shape and has a large area smaller than the planar surface area of the first plate P1. The first plate P1 has a stepped portion JW in the lower portion thereof due to the internal space 33. The stepped portion JW may function as a sidewall of the internal space 33. When the heater HT, preferably the planar heater 24, is provided in the internal space 33, the stepped portion JW may guide a seating position of the planar heater 24. The internal space 33 communicates with a post insertion portion 21.

Meanwhile, the internal space 33 may be provided in the second plate P2. In this case, the internal space 33 is formed concavely in an upper portion of the second plate P2. The second plate P2 may include a stepped portion in the upper portion thereof due to the internal space 33. When the second plate P2 is provided with the post 22, the post 22 is provided to protrude from the bottom surface of the internal space 33 beyond the body BD of the second plate P2.

Referring to FIG. 7, in the susceptor 20 according to the preferred embodiment of the present disclosure, at least one of the first and second plates P1 and P2 is provided with a plurality of posts 22 and the remaining one of the first and second plates is provided with a plurality of post insertion portions 21. The post insertion portions 21 may be in the form of recesses or may be in the form of holes. When the post insertion portions 21 are provided in the form of recesses, an upper portion of the first plate P1 may have a closed shape.

In the susceptor 20 according to the preferred embodiment of the present disclosure, the first plate P1 may be provided with the post insertion portions 21, and the second plate P2 may be provided with the posts 22.

In the susceptor 20 according to the preferred embodiment of the present disclosure, the first and second and are coupled to each other by plates P1 P2 correspondingly inserting the posts 22 to the post insertion portions 21. In the susceptor 20 according to the preferred embodiment of the present disclosure, the first and second plates P1 and P2 are fastened to each other by the posts 22 and the post insertion portions 21 provided in the first and second plates, respectively.

Here, in the planar heater 24 according to the preferred embodiment of the present disclosure provided between the first and second plates P1 and P2, the post holes 25 are provided at positions corresponding to the posts 22 and the post insertion portions 21. The posts 22 provided in the second plates P2 are inserted into the post insertion portions 21 provided in the first plate P1. The internal space 33 may be provided in the first plate P1. Accordingly, the second plate P2 is fastened to the first plate P1 by placing at least a portion of each post 22 in the internal space 33 and the remain portion of the post in each post insertion portion 21. Accordingly, the posts 22 are inserted into the post insertion portions 21 through the post holes 25 according to the preferred embodiment of the present disclosure.

The post holes 25 may be provided in different sizes depending on the area where they are provided (specifically, the central area 28 including the unit central area 28a or the peripheral area 29 including the unit peripheral area 29a).

In detail, referring to FIG. 2, the susceptor 20 according to the preferred embodiment of the present disclosure include a lift pin 32 at a peripheral portion thereof for lifting the substrate WP seated on the upper surface of the susceptor 20. Therefore, each of the first and second plates P1 and P2 and the planar heater 24 according to the preferred embodiment of the present disclosure provided between the first and second plates P1 and P2 is provided with a lift pin hole 31 for providing the lift pin 32. The first and second plates P1 and P2 have the respective lift pin holes 31 at corresponding positions. In addition, the planar heater 24 is provided with the lift pin hole 31 at a position corresponding to the lift pin holes 31 provided in the first and second plates P1 and P2.

In the planar heater 24 according to the preferred embodiment of the present disclosure, the post holes 25 in the peripheral area 29 of the planar heater 24 corresponding to the peripheral portion of the susceptor 20 is provided in a relatively large size in order to form the left pin hole 31 more efficiently.

The present disclosure will be described in detail with reference to FIG. 7. FIG. 7 schematically illustrates a side sectional view of the susceptor 20 according to the preferred embodiment of the present disclosure, with the first and second covers 24d and 24e omitted.

The upper view of FIG. 7 is a side sectional view of at least a portion of the peripheral portion of the susceptor 20 according to the preferred embodiment of the present disclosure before friction stir welding is performed. In this case, the peripheral portion of the susceptor 20 corresponds to the peripheral area 29 of the planar heater 24 according to the preferred embodiment of the present disclosure, and more specifically, to the unit peripheral area 29a.

Referring to the upper view of FIG. 7, the posts 22 are inserted into the post insertion portions 21 at positions corresponding to the post holes 25 provided in the unit peripheral area 29a.

The lower view of FIG. 7 is a side sectional view of at least the portion of the peripheral portion of the susceptor 20 after friction stir welding is performed. Referring to the lower view of FIG. 7, in the susceptor 20 according to the preferred embodiment of the present disclosure, after inserting the posts 22 into the post insertion portions 21, friction stir welding is performed on insertion areas. Each of the insertion areas may be an area where an outer surface of each of the posts 22 and an inner surface of each of post insertion portions 21 come into contact with each other to form an interface.

Referring to the lower view of FIG. 7, in the susceptor 20 according to the preferred embodiment of the present disclosure, friction stir welding is performed to form a wide welding area W so that the interface existing in each of the insertion areas included in the peripheral portion of the susceptor 20 is entirely removed. Accordingly, each of the insertion areas at the peripheral portion of the susceptor 20 is in a state in which there is no interface between the first and second plates P1 and P2 and includes an integrated welding area W.

In the susceptor 20 according to the preferred embodiment of the present disclosure, a lift pin hole 31 is provided in a welding area W formed corresponding to each of the post holes 25, each of the posts, and each of the post insertion portions 21 by friction stir welding. The lift pin hole 31 may be formed by performing friction stir welding on a corresponding insertion area and then performing hole processing.

In the planar heater 24 according to the preferred embodiment of the present disclosure, the post holes 25 in the peripheral area 29 corresponding to the peripheral portion of the susceptor 20 are provided in a relatively large size. With this, after forming welding areas W through friction stir welding on the insertion areas included in the peripheral portion of the susceptor 20, hole processing for lift pin holes 31 in the welding areas W may be performed more efficiently.

Specifically, unlike the planar heater 24 according to the preferred embodiment of the present disclosure, when a relatively small post hole is provided in the peripheral area, this may cause damage to the area around the post hole when hole processing is performed after forming a welding area W. In other words, this may result in a decrease in hole processing efficiency.

However, in the planar heater 24 according to the preferred embodiment of the present disclosure, the post holes 25 in the peripheral area 29 for forming the lift pin holes 31 are provided in a relatively large size, considering that lift pins are provided at the peripheral portion of the susceptor 20 according to the preferred embodiment of the present disclosure.

The planar heater 24 according to the preferred embodiment of the present disclosure is provided in advance with a structure to prevent a decrease in the efficiency during hole processing of the lift pin hole 31. The susceptor 20 according to the preferred embodiment of the present disclosure may be efficiently provided with the lift pin 32 by including the planar heater 24 according to the preferred embodiment of the present disclosure.

The susceptor 20 according to the preferred embodiment of the present disclosure uses friction stir welding to join the first and second plates P1 and P2 together. Friction stir welding is a method of welding a material without melting it. Therefore, compared to conventional melt welding or joining methods, the generation of defects such as pores, solidification cracks, and residual stress caused by the transformation from liquid to solid is small. In addition, the mechanical properties are excellent because deformation hardly occurs.

The welding area W formed by such friction stir welding has high strength and weldability. In addition, the welding area W does not include an interface between the first and second plates P1 and P2.

In the susceptor 20 according to the preferred embodiment of the present disclosure, the efficiency of hole processing may be increased through the planar heater 24 in which the post holes 25 in the peripheral area 29 are provided in a relatively large size. In addition, the problem of particles generated during hole processing moving along the interface and damaging or interfering with the planar heater 24 may be prevented through the welding area W that does not include the interface.

In the susceptor 20 according to the preferred embodiment of the present disclosure, friction stir welding may be performed not only on the peripheral portion of the susceptor 20 but also on insertion areas included in the central portion of the susceptor 20.

The susceptor 20 according to the preferred embodiment of the present disclosure does not include an additional component (for example, a lift pin 32) at the central portion of the susceptor 20 unlike the peripheral portion of the susceptor 20. Accordingly, the post holes 25 provided in the central area 28 of the planar heater 24 are provided only for joining the first and second plates P1 and P2. Therefore, the post holes 25 provided in the central area 28 are provided in a relatively small size.

The upper view of FIG. 8 is a view illustrating a fastening state of first and second plates P1 and P2 before welding to a susceptor 20 according to a preferred embodiment of the present disclosure. The lower view of FIG. 4 is a view illustrating the susceptor 20 according to the preferred embodiment of the present disclosure. In FIG. 4, the susceptor 20 according to the preferred embodiment of the present disclosure is schematically illustrated.

As illustrated in the upper view of FIG. 8, in the susceptor 20 according to the preferred embodiment of the present disclosure, the first and second plates P1 and P2 are fastened to each other by a plurality of posts 22 and a plurality of post insertion portions 21 provided in the first and second plates, respectively.

In the susceptor according to the preferred embodiment of the present disclosure, a border portion B1 of the first plate P1 and a border portion B2 of the second plate P2 come into contact with each other due to the fastening of the first and second plates P1 and P2 through the posts 22 and the post insertion portions 21. With this, interfaces between the first and second plates P1 and P2 exist at a border portion SB of the susceptor 20.

The border portion B1 of the first plate P1 is a portion surrounding an internal space 33 and a post insertion portion existing area IF where the post insertion portions 21 exist. The border portion B2 of the second plate P2 is a portion surrounding a post existing area PF where the posts 22 exist. In the susceptor 20 according to the preferred embodiment of the present disclosure, an interface between the first and second plates P1 and P2 exists at the border portion SB of the susceptor 20 as a surface of the border portion B1 of the first plate P1 and a surface of the border portion B2 of the second plate P2 corresponding to the surface of the border portion B1 of the first plate P1 are in contact with each other.

In the susceptor 20 according to the preferred embodiment of the present disclosure, welding is performed on the border portion SB and insertion areas IP of the susceptor 20. Preferably, friction stir welding may be performed.

Referring to the lower view of FIG. 8, the border portions B1 and B2 of the first and second plates P1 and P2 are welded and integrated together. Specifically, the interface between the first and second plates P1 and P2 is removed by welding, the interface existing at the border portions B1 and B2 of the first and second plates P1 and P2 due to the contact between the surface of the border portion B1 of the first plate P1 and the surface of the border portion B2 of the second plate P2 corresponding thereto. Here, the welding may result in the removal of at least a portion of the interface between the first and second plates P1 and P2 or the removal of the entire interface between the first and second plates P1 and P2. In the lower view of FIG. 8, it is illustrated that at least the portion of the interface between the first and second plates P1 and P2 existing at the border portions B1 and B2 of the first and second plates P1 and P2 is removed by welding.

In the susceptor 20 according to the preferred embodiment of the present disclosure, a welding area W is formed by performing welding on the border portions B1 and B2 of the first and second plates P1 and P2. The border portion SB of the susceptor 20 according to the preferred embodiment of the present disclosure including the border portions B1 and B2 of the first and second plates P1 and P2 may prevent inflow of particles such as dust from the outside by including the welding area W.

Specifically, the welding area W provided at the border portion SB of the susceptor 20 according to the preferred embodiment of the present disclosure is formed while removing the interface between the first and second plates P1 and P2 existing at the border portion SB of the susceptor 20. The welding area W of the border portion SB of the susceptor 20 is formed while removing at least the portion of the interface between the first and second plates P1 and P2. Accordingly, the remaining portions of the interface between the first and second plates P1 and P2 may exist on opposite sides of the welding area W of the border portion SB of the susceptor 20.

The welding area W provided at the border portion SB of the susceptor 20 may be in the form of removing the interface between the first and second plates P1 and P2 at the border portion SB of the susceptor 20 connected to an insertion area IP. However, as the welding area W of the border portion SB of the susceptor 20 removes at least the portion of the interface between the first and second plates P1 and P2 at the border portion SB of the susceptor 20, the remaining portions of the interface between the first and second plates P1 and P2 may exist on the opposite sides of the welding area. Accordingly, the portion of the interface between the first and second plates P1 and P2 located inside the welding area W may be connected to the insertion area. The portion of the interface between the first and second plates P1 and P2 located outside the welding area W is not connected to the insertion area IP.

The welding area W of the border portion SB of the susceptor 20 is in the form of dividing the interface between the first and second plates P1 and P2 existing at the border portion SB of the susceptor 20. Accordingly, the welding area W of the border portion SB of the susceptor 20 is interposed between the interface of the first and second plates P1 and P2 located inside the welding area W and the interface of the first and second plates P1 and P2 located outside the welding area W. Therefore, the welding area W of the border portion SB of the susceptor 20 may prevent particles such as dust flowing through the interface of the first and second plates P1 and P2 outside the welding area W from moving to the interface of the first and second plates P1 and P2 inside the welding area W. As a result, the particles may be prevented from flowing into the internal space 33. Furthermore, the particles flowing into the internal space 33 may be prevented from negatively affecting the heater HT provided in the internal space 33.

As illustrated in FIG. 9, the border portion SB of the susceptor 20 including the border portions B1 and B2 of the first and second plates P1 and P2 is welded. Welding is performed entirely along the border portion SB of the susceptor 20. Accordingly, a continuous welding area W is formed at the border portion SB of the susceptor 20.

In the susceptor 20 according to the preferred embodiment of the present disclosure, interfaces between the first and second plates P1 and P2 exist in the insertion areas IP where the posts 22 are inserted into the post insertion portions 21 as the first and second plates P1 and P2 are in contact with each other.

In the susceptor 20 according to the preferred embodiment of the present disclosure, welding is performed on the interfaces existing in the insertion areas IP. Each of the insertion areas IP is an area where each of the posts 22 is inserted into each of the post insertion portions 21. Accordingly, an interface between the first and second plates P1 and P2 may exist in the insertion area IP due to the contact between the post insertion portion 21 and the post 22. The post 22 and the post insertion portion 21 in the insertion area IP are welded and integrated together.

In the susceptor 20 according to the preferred embodiment of the present disclosure, both the peripheral portion of the susceptor 20 and the central portion of the susceptor 20 are welded. With this, when heating the susceptor 20 according to the preferred embodiment of the present disclosure, the susceptor 20 may be prevented from expanding only the central portion thereof, thereby preventing a decrease in surface flatness of the susceptor 20.

Unlike the susceptor 20 according to the preferred embodiment of the present disclosure, when only the peripheral portion of the susceptor is welded, the central portion of the susceptor still has the interfaces between the first and second plates P1 and P2 and may include air. In this case, when the susceptor is heated by the heater HT provided in the internal space 33, only the central portion of the susceptor may expand. As a result, the surface flatness of the susceptor may decrease, and the flatness of the substrate WP seated on the upper surface of the susceptor may change. This may lead to product defects.

However, in the susceptor 20 according to the preferred embodiment of the present disclosure, the posts 22 and the post insertion portions 21 are provided at both the peripheral portion of the susceptor 20 and the central portion of the susceptor 20 and are mechanically temporarily coupled to each other. Then, welding areas W are formed in the insertion areas IP, which are mechanical coupling areas. In the susceptor 20 according to the preferred embodiment of the present disclosure, the posts 22 and the post insertion portions 21 are completely integrated together through the welding areas W. With this, the susceptor 20 according to the preferred embodiment of the present disclosure may be prevented from causing the problem of the central portion of the susceptor 20 expanding when heated by the heater HT. Accordingly, the surface flatness of the susceptor 20 according to the preferred embodiment of the present disclosure may be maintained good. Furthermore, deterioration of the flatness of the substrate WP may be prevented, and product defects may be minimized.

Referring to the upper view of FIG. 8, the post insertion portions 21 are provided in the form of holes, as an example. Each of the posts 22 has an upper surface exposed by an opening of each of the post insertion portions 21, and opposite side surfaces in contact with an inner surface of the post insertion portion 21. Referring to FIG. 9, the interfaces of the insertion areas IP exist in areas where the openings of the post insertion portions 21 are formed. When the post insertion portions 21 are provided in the form of holes, the interfaces of the insertion areas IP may be easily perceived with the naked eye. Accordingly, welding positions in the insertion areas IP may be more easily identified.

Referring to the lower view of FIG. 8, in the susceptor 20 according to the preferred embodiment of the present disclosure, welding is performed on the interfaces existing in the insertion areas IP. As a result, the welding areas W are formed at positions corresponding to the insertion areas IP.

Referring to FIG. 9, the welding areas W of the insertion areas IP are provided separately from the welding area W of the border portion SB of the susceptor 20. The welding areas W of the insertion areas IP are provided independently of each other by performing welding on the corresponding insertion areas IP. The welding may be performed continuously so that the welding areas W corresponding to the insertion areas IP are continuously formed together. However, in this case, portions other than the insertion areas IP may also be welded, causing deterioration of the efficiency of welding. Therefore, welding in the insertion areas IP is preferably performed so that the independent welding areas W are formed corresponding to the insertion areas IP.

Referring to FIG. 9, a projection area of each of the posts 22 with respect to a welding area W of each of the insertion areas IP may be located inside the welding area W of the insertion area IP. This may be implemented by performing welding on both the post 22 and the interface of the insertion area IP during welding of the insertion area IP. The welding area W is provided to have a width larger than that of the opening of the post insertion portion 21. In this case, an upper portion of the post 22 may be removed by the welding area W and integrated with the first plate P1.

In the susceptor 20 according to the preferred embodiment of the present disclosure, welding may be performed in consideration of width and depth so as not to damage the heater HT provided in the internal space 33.

The susceptor 20 according to the preferred embodiment of the present disclosure includes a lift pin 32. The lift pin 32 is provided at a position corresponding to a peripheral portion of the heater HT provided in the internal space 33 and is located at a peripheral portion of the internal space 33.

Referring to the lower view of FIG. 8, the susceptor according to the preferred embodiment of the present disclosure is provided with a lift pin hole 31 in a welding area W of a corresponding insertion area IP included in the peripheral portion of the internal space 33. Each of the post insertion portions 21 is formed to correspond to the width of each of the posts 22. Accordingly, when the width of the post 22 is increased, the width of the post insertion portion 21 is also increased. The susceptor 20 according to the preferred embodiment of the present disclosure may be provided with a post 22 having a relatively large width at a peripheral portion of the second plate P2, considering that it is provided with the lift pin hole 31. Accordingly, when forming the lift pin hole 31 by providing the welding area W in the insertion area IP corresponding to the post 22 having the large width, the efficiency of hole processing may be increased.

The present disclosure will be described in detail with reference to FIG. 10. FIG. 10 schematically illustrates a side sectional view of the susceptor 20 according to the preferred embodiment of the present disclosure, with the first and second covers 24d and 24e omitted.

Referring to FIG. 10, the upper view of FIG. 10 is a side sectional view of at least a portion of the central portion of the susceptor 20 according to the preferred embodiment of the present disclosure before friction stir welding is performed on insertion areas.

The central portion of the susceptor 20 according to the preferred embodiment of the present disclosure corresponds to the central area 28 of the planar heater 24 according to the preferred embodiment of the present disclosure, and more specifically, to the unit central area 28a.

The lower view of FIG. 10 and the upper view of FIG. are side sectional views of at least the portion of the central portion of the susceptor 20 according to the preferred embodiment of the present disclosure after friction stir welding is performed on the insertion areas.

Referring to the lower view of FIG. 10, friction stir welding is performed on the insertion areas. Here, friction stir welding may be performed on an interface between an inner surface of each of the post insertion portions 21 and an outer surface of each of the posts 22 in contact with the inner surface. As a result, the interface between the inner surface of the post insertion portion 21 and the outer surface of the post 22 may be welded to form a welding area W. In this case, at least a portion of the interface corresponding to a bottom portion of the inner surface of the post insertion portion 21 and an upper portion of the outer surface of the post 22 may not be welded.

The insertion areas included in the central portion of the susceptor 20 according to the preferred embodiment of the present disclosure are areas where joining of the first and second plates P1 and P2 is performed only. In other words, a separate process such as hole processing is not performed after joining the first and second plates P1 and P2 through friction stir welding.

Therefore, even when only an outer portion of the interface of the insertion area where the inner surface of the post insertion portion 21 and the outer surface of the post 22 are in contact with each other is removed through friction stir welding, this is sufficient to prevent interference between the insertion area and the planar heater 24.

Alternatively, friction stir welding may be performed on the entire interface between the inner surface of the post insertion portion 21 and the outer surface of the post 22 in contact with the inner surface.

Each of the post holes 25 in the central area 28 allows each of the posts 22 inserted into each of the post insertion portions 21 to pass therethrough and is used to join the first and second plates P1 and P2 through friction stir welding. Accordingly, the post holes 25 in the central area 28 are provided in a relatively smaller size than the post holes 25 in the peripheral area 29.

In the susceptor 20 according to the preferred embodiment of the present disclosure, friction stir welding is performed not only on the peripheral portion of the susceptor 20 but also on the central portion of the susceptor 20 to join the first and second plates P1 and P2. With this, when the susceptor 20 according to the preferred embodiment of the present disclosure is heated by the planar heater 24, the susceptor 20 may be prevented from expanding only the central portion thereof, thereby preventing a change in flatness of the substrate.

Unlike the susceptor 20 according to the preferred embodiment of the present disclosure, when only the peripheral portion of the susceptor is welded, the central portion of the susceptor still has the interfaces between the first and second plates P1 and P2 and may include air. In this case, when the susceptor is heated by the planar heater, only the central portion of the susceptor may expand. This may change the flatness of the substrate seated on the upper surface of the susceptor and lead to product defects.

However, in the susceptor 20 according to the preferred embodiment of the present disclosure, friction stir welding is performed also on the insertion areas included in the central portion of the susceptor 20 to join the first and second plates P1 and P2. In the susceptor 20 according to the preferred embodiment of the present disclosure, friction stir welding is performed on both the peripheral portion of the susceptor 20 and the central portion of the susceptor 20 to join the first and second plates P1 and P2. With this, when the susceptor 20 according to the preferred embodiment of the present disclosure is heated by the planar heater 24, the susceptor may be prevented from expanding only a portion of the entire area thereof including the peripheral portion and the central portion. Accordingly, the flatness of the substrate WP may be maintained good. As a result, the susceptor 20 according to the preferred embodiment of the present disclosure may be advantageous in minimizing product defects.

Referring again to FIGS. 8 and 9, the planar heater 24 according to the preferred embodiment of the present disclosure further includes a boundary post hole 27 located on the same horizontal line as the central terminal portion 26.

The boundary post hole 27 allows a post 22 to pass therethrough. An insertion area including the post 22 is integrated by welding and includes a welding area W. A lift pin hole 31 is provided in the welding area W. Accordingly, the boundary post hole 27 is preferably provided to have a relatively large width. This may be to prevent the planar heater 24 from being broken or damaged when forming the lift pin hole 31.

Specifically, the planar heater 24 according to the preferred embodiment of the present disclosure may be divided into four by a vertical division boundary 30a and a horizontal division boundary 30b. The unit planar heaters 24a are provided by the division boundary 30 including the vertical division boundary 30a and the horizontal division boundary 30b.

Each of the unit planar heaters 24a is provided with a depression DT having a semicircular cross-section at a side thereof located toward the horizontal division boundary 30b. In the planar heater 24 according to the preferred embodiment of the present disclosure, the terminal portion 26 is positioned and disposed to correspond to the hollow shaft 23 so that corresponding depressions DT of each adjacent pair of the unit planar heaters 24a are disposed to face each other. Due to having the semicircular cross-section, the depressions DT of each adjacent pair of the unit surface heaters 24a may be positioned to face each other to form a single circular hole. As a result, the boundary post hole 27 is formed.

The planar heater 24 according to the preferred embodiment of the present disclosure is provided with the boundary post hole 27 through which the post 22 passes by providing the depressions DT of the unit planar heaters 24a.

In the susceptor 20 according to the preferred embodiment of the present disclosure, the post 22 is passed through the boundary post hole 27 and inserted into a post insertion portion 21 corresponding thereto. The post 22 is provided around the hollow shaft 23 provided in the center of the second plate P2. Accordingly, the post 22 may be inserted into the corresponding post insertion portion 21 to form a mechanical coupling structure at the central portion of the susceptor 20 according to the preferred embodiment of the present disclosure.

Then, friction stir welding is performed on the insertion area including the boundary post hole 27. The boundary post hole 27 is formed by the depressions DT formed on at peripheral portions of the unit planar heaters 24a, and is provided in the central area 28 of the planar heater 24 according to the preferred embodiment of the present disclosure. In the susceptor 20 according to the preferred embodiment of the present disclosure, welding is performed on the insertion area including the boundary post hole 27, and preferably friction stir welding is performed. As a result, the post 22 and the post insertion portion 21 are joined together, thereby preventing the problem of the central portion of the susceptor 20 expanding when heated.

Although the preferred embodiments of the present disclosure have been disclosed for illustrative purposes, those skilled in the art will appreciate that various modifications, additions, and substitutions are possible, without departing from the scope and spirit of the present disclosure as disclosed in the accompanying claims.

1. A susceptor, comprising:
a first plate;
a second plate provided under the first plate; and
a planar heater provided between the first and second plates,
wherein the planar heater is in the form of a planar surface and comprises a heating pattern therein corresponding to an area of the planar surface.

2. The susceptor of claim 1, wherein the planar heater comprises:
a first film;
a second film provided under the first film; and
a heating pattern formed on at least one of the first and second films and provided between the first and second films.

3. The susceptor of claim 2, wherein the heating pattern is formed corresponding to an area of a planar surface of at least one of the first and second films.

4. The susceptor of claim 1, wherein the planar heater comprises:
at least one post hole; and
a terminal portion provided at a side of the planar heater.

5. The susceptor of claim 1, wherein the planar heater is divided,
wherein the divided planar heater is disposed so that the terminal portion of the planar heater corresponds to a hollow shaft of the second plate.

6. The susceptor of claim 1, wherein at least one of the first and second plates comprises a post and a remaining one of the first and second plates comprises a post insertion portion,
wherein the first and second plates are joined by welding an insertion area where the post is inserted into the post insertion portion.

7. The susceptor of claim 6, wherein the planar heater comprises at least one post hole corresponding to the post and the post insertion portion, and
the susceptor comprises a lift pin hole provided in a welding area corresponding to the post hole, the post, and the post insertion portion.

8. The susceptor of claim 7, wherein the at least one post hole comprises a plurality of post holes,
wherein a portion of the post holes has a relatively large size and a remaining portion of the post holes has a relatively small size, and
the lift pin hole is provided in the post hole having the large size.

9. The susceptor of claim 4, wherein the second plate comprises a hollow shaft extending from a center thereof toward a floor surface,
wherein the planar heater is disposed so that the terminal portion corresponds to the hollow shaft.

10. The susceptor of claim 1, wherein the susceptor comprises a heater seating recess provided in at least one of the first and second plates.

11. A susceptor provided by joining a first plate and a second plate together,
wherein at least one of the first and second plates comprises a post and a remaining one of the first and second plates comprises a post insertion portion,
wherein an internal space in which a heater is provided is provided inside a border portion of the at least one of the first and second plates, and the post is provided in the internal space,
wherein border portions of the first and second plates are welded and integrated together, and an insertion area where the insertion portion where the post is inserted into the post insertion portion is welded.

12. The susceptor of claim 11, wherein the insertion area is welded by friction stir welding.

13. The susceptor of claim 11, wherein the heater is provided as a planar heater,
wherein the planar heater comprises:
a first film;
a second film provided under the first film; and
a heating pattern formed on at least one of the first and second films and provided between the first and second films,
wherein the heating pattern is formed corresponding to an area of a planar surface of at least one of the first and second films.

14. The susceptor of claim 13, wherein the planar heater comprises:
at least one post hole; and
a terminal portion provided at a side of the planar heater.

15. The susceptor of claim 14, wherein the post hole corresponds to the post provided in the at least one of the first and second plates and the post insertion portion provided in the remaining one of the first and second plates, and
the susceptor comprises a lift pin hole provided in a welding area corresponding to the post hole, the post, and the post insertion portion.

16. The susceptor of claim 14, wherein the second plate comprises a hollow shaft extending from a center thereof toward a floor surface,
wherein the planar heater is disposed so that the terminal portion corresponds to the hollow shaft.
